(19) United States
(12) Patent Application Publication
(10) Pub. No.: US 2005/0009242 A1
(43) Pub. Date: Jan. 13, 2005

(54) Packaging method for thin integrated circuits

(76) Inventor: Jung-Chien Chang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/615,138

(22) Filed: Jul. 9, 2003

(51) Int. Cl. H01L 21/44

(52) U.S. Cl. 438/127

(57) ABSTRACT

A packaging method for preparing thin integrated circuits comprises: forming a circuit layer with multiple sections on a substrate; attaching multiple electronic elements to the circuit layer between two sections of the circuit layer; applying an encapsulant layer to protect the electronic elements; and removing the substrate to expose the circuit layer. By removing the substrate, the exposed circuit can be connected to another circuit board and the integrated circuit is much thinner.

### BACKGROUND OF THE INVENTION

1. Field of the Invention

The present invention relates to a package method for electronic elements, and more particularly to a packaging method for thin integrated circuits.

2. Description of Related Art

Electronics industry packaging technology is modifying integrated circuit structure to meet miniaturization demands.

For example, methods of packaging light emitting diode (LED) with integrated circuits attach multiple LEDs to a printed circuit board and cover the LEDs and printed circuit board with a molded transparent layer. The resultant integrated circuit with LEDs has a thickness equal to the printed circuit board and the transparent layer. The printed circuit board constitutes a specific proportion of the total thickness of the integrated circuit and constitutes an absolute minimum design limit.

The present invention provides a breakthrough in packaging methodology for thin integrated circuits.

### SUMMARY OF THE INVENTION

A first objective of the present invention is to provide a packaging method for thin integrated circuits to reduce production cost and reduce sizes of integrated circuits.

A second objective of the present invention is to provide a packaging method for thin integrated circuits that results in a thickness essentially the thickness of an encapsulant layer.

Further benefits and advantages of the present invention will become apparent after a careful reading of the detailed description in accordance with the drawings.

### BRIEF DESCRIPTION OF THE DRAWINGS

FIGS. 1A-1K are sequentially operational cross sectional side plan views of partial products of a thin integrated circuit formed with a packaging method in accordance with the present invention;

FIG. 2 is a cross sectional side plan view of another embodiment of the thin integrated circuits having a flat surface formed with the packaging method in accordance with the present invention;

FIGS. 3A-3D are side plan views in partial section of four embodiments of thin integrated circuits having multiple rectangular dimples formed with the packaging method in accordance with the present invention;

FIGS. 4A-4C are side plan views in partial section of three embodiments of thin integrated circuits having multiple tin balls formed with the packaging method in accordance with the present invention; and

FIGS. 5A-5B are side plane view of two embodiments of thin integrated circuit of small outline package (SOP) formed with the packaging method in accordance with the present invention.

### DETAILED DESCRIPTION OF THE PREFERRED EMBODIMENT

A packaging method for thin integrated circuits in accordance with the present invention accommodates multiple electronic elements on a circuit layer for each thin integrated circuit. For purposes of illustration only, a method of packaging a specific thin integrated circuit with LEDs is described. Numerous integrated circuits with different electronic elements can be packaged with the packaging method.

The packaging method for thin integrated circuits having electronic elements comprises:

forming a circuit layer with multiple sections on a substrate;

attaching multiple electronic elements to the circuit layer;

applying an encapsulant layer to protect the electronic elements; and

removing the substrate to expose the circuit layer.

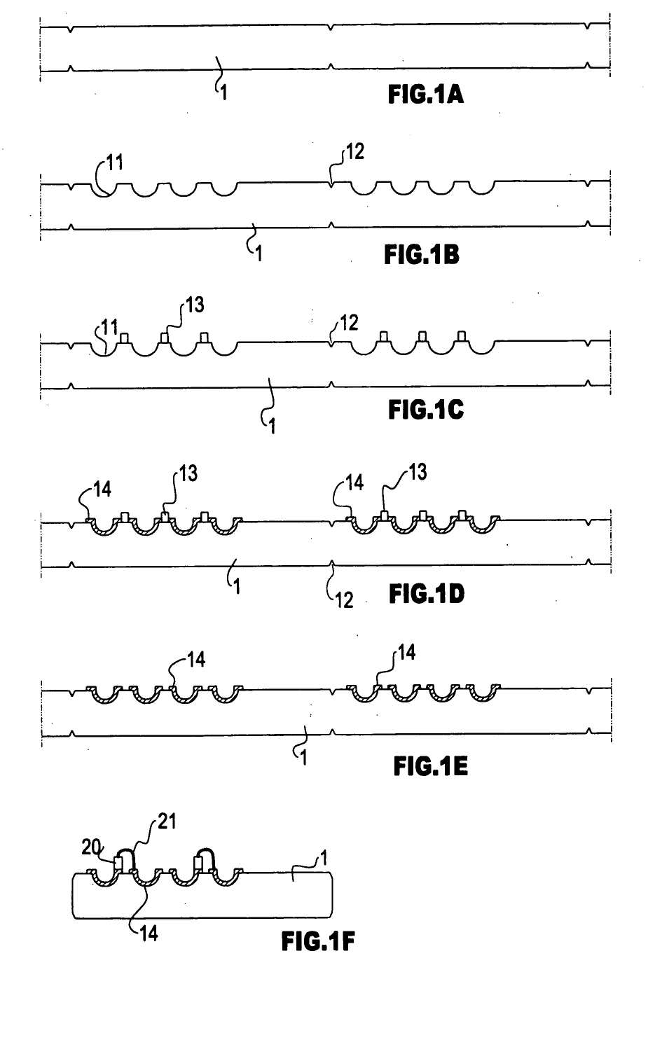

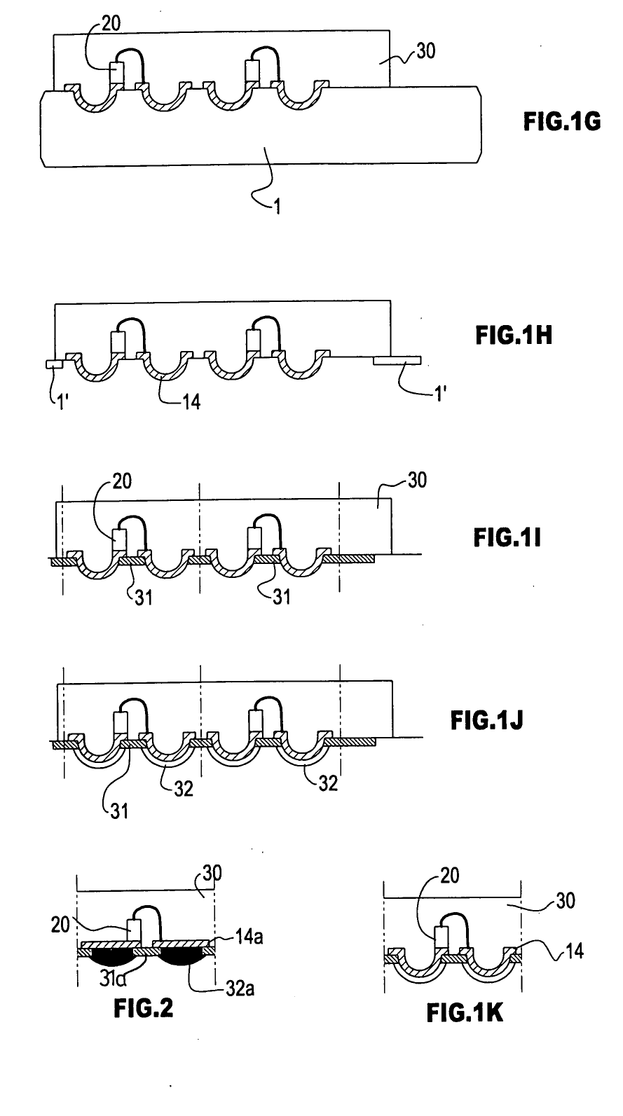

With reference to FIGS. 1A and 1B, a substrate (1) made of copper is obtained and has a top face (not numbered), a bottom face (not numbered), multiple curved dimples (11) and multiple cutting grooves (12). The curved dimples (11) are defined in the top face by etching, and the cutting grooves (12) are defined in pairs respectively in the top face and the bottom face. Adjacent pairs of cutting grooves (12) intersecting with other adjacent pairs of cutting grooves (12) define boundaries of individual integrated circuit units.

With reference to FIGS. 1C and 1D, photo-resist (13) is selectively applied to the top face of the substrate (1) between adjacent curved dimples (11) within the integrated circuit unit. Then, a circuit layer (14) is selectively electroplated on areas of the top face of the substrate (1) without the photo-resist (13). The circuit layer (14) has a thickness and is an anticorrosive metal suitable for lead-tin soldering so gold or aluminum wires can be bonded to the circuit layer (14). The circuit layer (14) is composed of a multi-ply metallic layer optionally of copper/nickel/copper/pure nickel/pure gold, pure nickel/pure gold, pure nickel/gold/palladium, etc. The thickness of the circuit layer (14) is preferred to be 3 μm to accommodate current desired in the circuit. After electroplating the circuit layer (14) on the substrate (1), the photo-resist (13) is removed.

With reference to FIGS. 1E and 1F, after removing the photo-resist from the substrate (1), the substrate (1) is divided along the cutting grooves (12) into individual integrated circuit units. Multiple windows (not numbered) are formed between two areas of the circuit layer (14) after the photo-resist is removed so that the circuit layer (14) has multiple sections and the sections are disconnected. Then, an LED (20) with two ends bridges between two adjacent sections of the circuit layer (14). One end of the LED (20) is soldered on one section with silver-paste and the other end of the LED (20) is connected to the adjacent section with a conductive wire (21).

With reference to FIG. 1G, an encapsulant layer (30) is applied to the entire top face of the substrate (10) by molding after attaching the LEDs (20) or other multiple electronic elements (not shown) and covers the LEDs (20) or multiple electronic elements to protect the circuit layer (14). The encapsulant layer (30) is selectively made of transparent material to allow light from the LEDs (20) to emit through the encapsulant layer (30).

With reference to FIGS. 1H and 1I, after molding the encapsulant layer (30), the substrate (1) is etched and removed from the bottom face to expose the circuit layer (14) and sections of the encapsulant layer (30). With the substrate (1) removed, the circuit layer (14) at the curved dimples (11) in the substrate (1) become protrusions (not numbered) that can connect to other circuit boards. Optionally, parts of the substrate are retained and served as a lead-frame (1′) at opposite edges of individual integrated circuit units for testing the integrated circuit or for bending to be gull-wing leads. Then, an isolating layer (31) is formed between two protrusions on the circuit layer (14) and covers the sections of the encapsulant layer (30), wherein the insolating layer (31) is white and has reflect light emitted from the LEDs (20).

With reference to FIGS. 1J and 1K, a tin-paste layer (32) is applied to the circuit layer (14) between adjacent isolating layers (31) so the integrated circuit unit can be easily soldered and electrically connected to other circuit boards. Whereby, a thin integrated circuit having multiple LEDs (20) is achieved. Selectively, the thin integrated circuit unit can be formed with a single LED (20) or electronic component.

With reference to FIG. 2, another embodiment of the integrated circuit uses a flat substrate (not numbered) without dimples. The circuit layer (14a) is formed on a flat substrate (not shown) using the same method previously described. Moreover, the flat substrate is also removed by etching to expose the circuit layer (14a). Finally, the isolating layers (31a) (not found in the drawing) and the tin-paste layers (32a) are formed on the circuit layer (14a) to achieve the integrated circuit. Wherein the tin-paste layers (32a) extend beyond the isolating layers (31a) to connect to other integrated circuits. Since the circuit layer (14a) does not have any protrusions, the thickness of the integrated circuit is reduced to diminish the size of the integrated circuit.

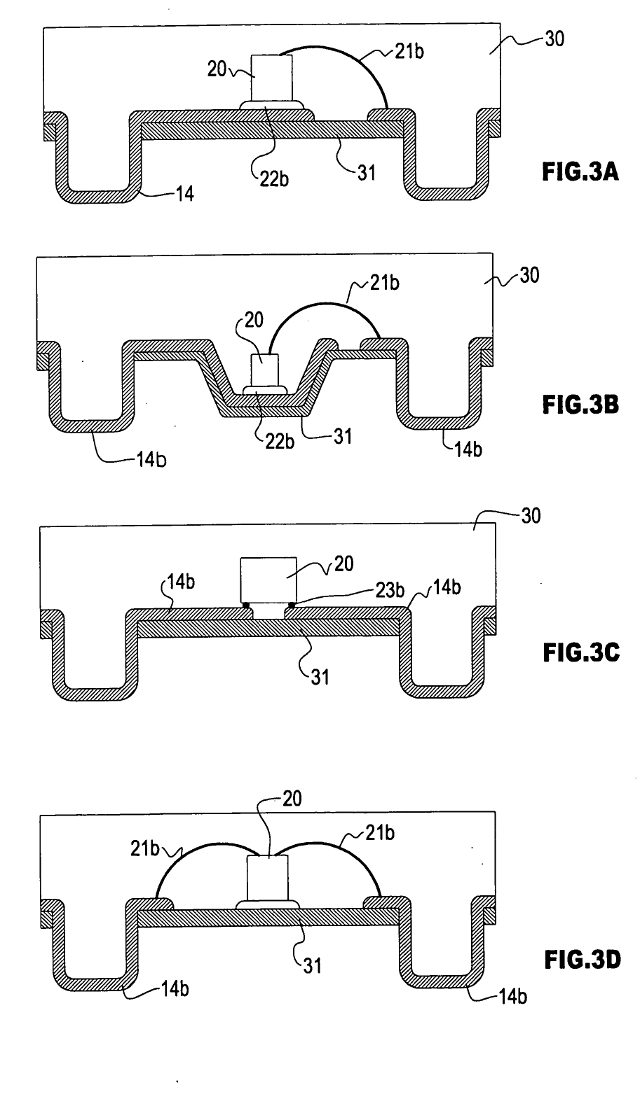

With reference to FIGS. 3A to 3D, the dimples (not numbered) in the integrated circuits may be rectangular. In FIG. 3A, the LED (20) has two ends (not numbered) with one end soldered to the circuit layer (14b) with silver paste (22b) and the other end connected to an adjacent section of the circuit layer (14b) by a conductive wire (21b). In FIG. 3B, the LED (20) is mounted in a recess (not numbered) and is also connected to two sections of the circuit layer (14b) by silver paste (22b) and a conductive wire (21b). In FIG. 3C, the LED (20) bridges a window (not numbered) in the circuit layer (14b) to connect two sections of the circuit layer (14b) by tin balls (23b). In FIG. 3D, the LED (20) is located in an enlarged window (not numbered) in the circuit layer (14b) and connects two sections of the circuit layer (14b) by conductive wires (21b).

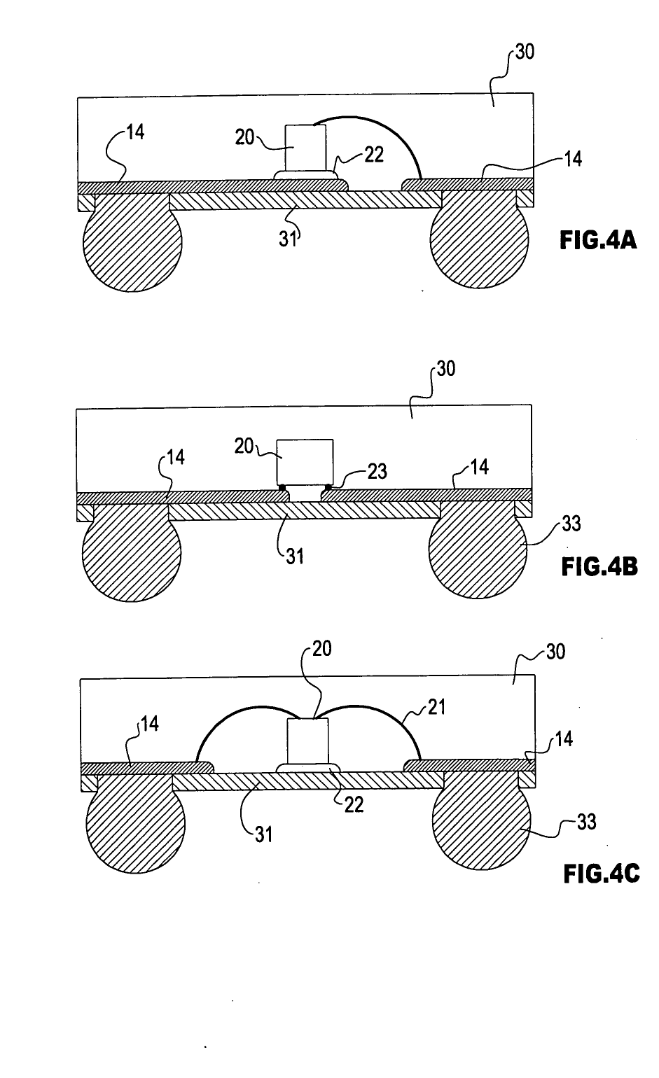

With reference to FIGS. 4A-4C, multiple round dimples (not numbered) are defined in the substrate (not shown) and filled with tin-paste to form tin balls (33). After etching the substrate, the tin balls (33) protrude and serve to solder the integrated circuit to another circuit board. An isolating layer (31) is applied to the integrated circuit.

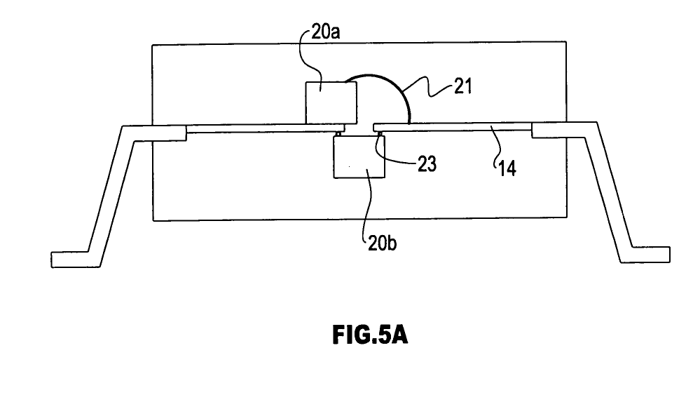

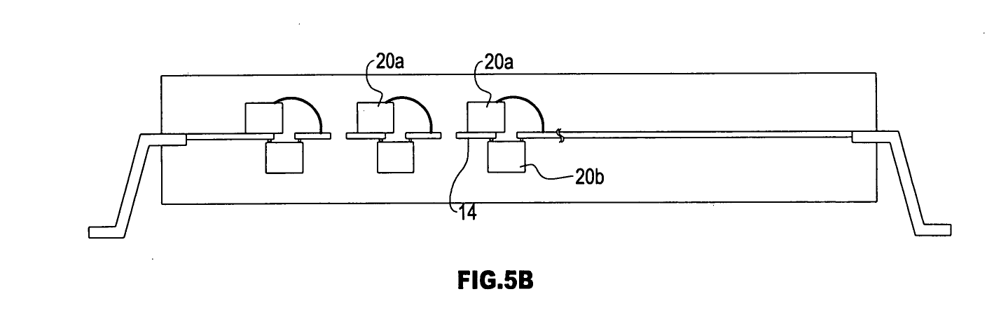

With reference to FIGS. 5A and 5B, another embodiment of the thin integrated circuit formed with the method in accordance with the present invention has electronic elements (20a, 20b) attached to two sides of the circuit layer (14). Such thin integrated circuits are known as Small Outline Package (SOP) products. In this embodiment, at least one top electronic element (20a) is mounted on a top of the circuit layer (14), the top electronic elements (20a) are cover with a top encapsulant layer (not numbered), and then the substrate (not shown) is removed by etching. Part of the substrate is retained at two distal edges in the shape of long strips to bend into gull-winged lead frame to connect the integrated circuit to another circuit board. At least one bottom electronic element (20b) is attached to a bottom of the circuit layer (14), and the bottom is covered with a bottom encapsulant layer (not numbered). Removing the substrate causes the integrated circuit to be much thinner than the conventional integrated circuit.

Although the invention has been explained in relation to its preferred embodiment, many other possible modifications and variations can be made without departing from the spirit and scope of the invention as hereinafter claimed.

1. A packaging method for thin integrated circuits comprising:
forming a circuit layer with multiple sections on a substrate;
attaching at least one electronic element to the circuit layer to connect two sections of the circuit layer;
applying an encapsulant layer to protect the electronic elements; and
removing the substrate to expose the circuit layer.

2. The packaging method as claimed in claim 1, wherein multiple dimples are defined in the substrate before the circuit layer is formed on the substrate and in the dimples;
whereby, the circuit layer at the dimples become protrusions after the substrate is removed.

3. The packaging method as claimed in claim 1, wherein the substrate has a flat top face and the circuit layer formed on the substrate is flat.

4. The packaging method as claimed in claim 1, wherein the at least one electronic element is connected to the circuit layer by bonding metal wires between the at least one electronic element and the circuit layer.

5. The packaging method as claimed in claim 2, wherein the at least one electronic element is connected to the circuit layer by bonding metal wires between the at least one electronic element and the circuit layer.

6. The packaging method as claimed in claim 3, wherein the at least one electronic element is connected to the circuit layer by bonding metal wires between the at least one electronic element and the circuit layer.

7. The packaging method as claimed in claim 1, wherein the at least one electronic element is connected to the circuit layer by tin balls between the at least one electronic element and the circuit layer.

8. The packaging method as claimed in claim 2, wherein the at least one electronic element is connected to the circuit layer by tin balls between the at least one electronic element and the circuit layer.

9. The packaging method as claimed in claim 3, wherein at least one the electronic element is connected to the circuit layer by tin balls between the at least one electronic element and the circuit layer.

10. The packaging method as claimed in claim 1, wherein parts of the substrate are retained after etching, are bent and serve as a gull-winged lead frame.

11. The packaging method as claimed in claim 2, wherein parts of the substrate are retained after etching, are bent and serve as a gull-winged lead frame.

12. The packaging method as claimed in claim 3, wherein parts of the substrate are retained after etching, are bent and serve as a gull-winged lead frame.

13. The packaging method as claimed in claim 1, wherein an isolating layer is applied between adjacent sections of the exposed circuit layer after the substrate is removed, wherein the isolating layer reflects light.

14. The packaging method as claimed in claim 1, wherein the at least one electronic element is a light emitting diode.

15. The packaging method as claimed in claim 14, wherein an isolating layer is applied between adjacent sections of the exposed circuit layer after the substrate is removed, wherein the isolating layer reflects light.

16. The packaging method as claimed in claim 1, wherein after removing the substrate, the packaging method further comprises:
attaching at least one bottom electronic element under the exposed circuit layer; and
applying a bottom encapsulant layer to protect the at least one electronic element.
